(19) United States
(12) Patent Application Publication
(10) Pub. No.: US 2025/0311545 A1
(43) Pub. Date: Oct. 2, 2025

(54) DISPLAY PANEL AND DISPLAY DEVICE

(71) Applicant: HKC CORPORATION LIMITED, Shenzhen (CN)

(72) Inventors: Qin LIANG, Shenzhen (CN); Zhisheng XIE, Shenzhen (CN); Yangling TANG, Shenzhen (CN); Xiufeng ZHOU, Shenzhen (CN); Haijiang YUAN, Shenzhen (CN)

(73) Assignee: HKC CORPORATION LIMITED, Shenzhen (CN)

(21) Appl. No.: 19/093,273

(22) Filed: Mar. 28, 2025

(30) Foreign Application Priority Data
Mar. 28, 2024 (CN) 202410381257.X

(51) Int. Cl. H10K 59/121; H10K 59/122; H10K 59/124

(52) U.S. Cl. CPC H10K 59/121; H10K 59/122; H10K 59/124

(57) ABSTRACT

Disclosed are a display panel and a display device. The display panel includes an array substrate, a flat layer and a light-emitting functional layer, the flat layer and the light-emitting functional layer being sequentially located on the array substrate, the light-emitting functional layer includes a plurality of pixel units distributed in an array, the pixel unit includes a display pixel and at least two irregular interference pixels, the flat layer is provided with irregular grooves of the same shape as the irregular interference pixels, an angle between at least part of an inner wall of the irregular groove and the array substrate is not equal to 90° or 180°, and the irregular interference pixel is provided in the irregular groove, so that a distance between the display pixel and the array substrate is greater than a distance between the irregular interference pixel and the array substrate.

### CROSS-REFERENCE TO RELATED APPLICATIONS

The present application claims all the benefits of the Chinese patent application No. 202410381257.X, filed on Mar. 28, 2024 before the China National Intellectual Property Administration of the People's Republic of China, entitled “Display Panel and Display Device”, which is explicitly incorporated herein by reference in its entirety.

### FIELD

The present application relates to the technical field of display, in particular to a display panel and a display device.

### BACKGROUND

With the increasing awareness of user security protection, contemporary people's desire for privacy protection is growing, which leads to a great market demand for anti-peeping technology for display devices.

In the related art, interference pixels are configured, and black shading units are disposed on light emergent sides of the interference pixels to block light emergent in a front view and limit small-angle light emergence of the interference pixels. As a result, display of normal pixels is affected and large-angle visibility is avoided.

However, in the related art, the black shading units corresponding to the interference pixels reduce the aperture ratio and luminance of a display panel, resulting in poor user experience.

### SUMMARY

The present application aims to provide a display panel and a display device to solve the technical problem of poor luminance of an anti-peeping display panel in the related art.

In a first aspect, an embodiment of the present application provides a display panel comprising an array substrate, a flat layer and a light-emitting functional layer, the flat layer and the light-emitting functional layer being sequentially located on the array substrate, wherein the light-emitting functional layer comprises a plurality of pixel units distributed in an array, the pixel unit comprises a display pixel and at least two irregular interference pixels, the flat layer is provided with irregular grooves of the same shape as the irregular interference pixels, an angle between at least part of an inner wall of the irregular groove and the array substrate is not equal to 90° or 180°, and the irregular interference pixel is provided in the irregular groove, so that a distance between the display pixel and the array substrate is greater than a distance between the irregular interference pixel and the array substrate.

In a possible embodiment, the inner wall of the irregular groove includes two inclined surfaces or at least one curved surface.

In a possible embodiment, light emitted by two opposite parts of the irregular interference pixel forms an angle with light emitted by the display pixel.

In a possible embodiment, each of the irregular grooves comprises at least two connected irregular sub-grooves, and an inner wall of each of the irregular sub-grooves comprises a curved surface or two inclined surfaces.

In a possible embodiment, a cross-sectional shape of the irregular interference pixel comprises at least one curved surface or two inclined surfaces.

In a possible embodiment, the inner wall of the irregular groove comprises two inclined surfaces, and cross-sectional shapes of the irregular interference pixel and the irregular groove are a V shape.

In a possible embodiment, a cross-sectional shape of the irregular sub-groove is a V shape, and cross-sectional shapes of the irregular interference pixel and the irregular groove are two consecutive V shapes.

In a possible embodiment, a cross-sectional shape of the irregular sub-groove is a concave V shape, and cross-sectional shapes of the irregular interference pixel and the irregular groove are two consecutive concave V shapes.

In a possible embodiment, a cross-sectional shape of the irregular sub-groove is a concave V shape, and cross-sectional shapes of the irregular interference pixel and the irregular groove are three concave V shapes.

In a possible embodiment, a cross-sectional shape of the irregular sub-groove is a convex V shape, and cross-sectional shapes of the irregular interference pixel and the irregular groove are two consecutive convex V shapes.

In a possible embodiment, the inner wall of the irregular groove comprises a curved surface, and cross-sectional shapes of the irregular interference pixel and the irregular groove are semi-circular.

In a possible embodiment, a connecting wall is further provided between the adjacent irregular sub-grooves, and the connecting wall is disposed parallel to the array substrate, so that the irregular interference pixel on the connecting wall is straight; and a length range of the connecting wall is ⅓ to ½ of an orthographic projection length of the irregular sub-groove on the array substrate.

In a possible embodiment, the connecting wall blunts an angle of a part connecting two V shapes or two convex V shapes.

In a possible embodiment, a connecting surface is provided between the two adjacent inclined surfaces of the irregular groove, and the connecting surface is disposed parallel to the array substrate, so that the irregular interference pixel on the connecting surface is straight; and a length range of the connecting surface is ⅓ to ½ of an orthographic projection length of the irregular groove on the array substrate.

In a possible embodiment, the at least two spaced irregular grooves are provided between the adjacent display pixels, the two irregular interference pixels are provided in the two irregular grooves respectively, and an arrangement direction of the two irregular interference pixels is a long side direction of the display pixels.

In a possible embodiment, a sum of lengths of the two irregular interference pixels and a gap length between the two irregular interference pixels is equal to a length of the display pixel.

In a possible embodiment, anodes of the two irregular interference pixels between the adjacent display pixels are connected into an integrated structure; and/or two shading units are disposed at intervals above the two irregular interference pixels between the adjacent display pixels, respectively.

In a possible embodiment, an angle between an extension line or tangent line at a middle position of a side wall of the irregular groove and a light emergent direction ranges from 10° to 80°.

In a possible embodiment, the display panel further comprises a packaging layer located on a light emergent side of the light-emitting functional layer, wherein the packaging layer comprises a first inorganic layer, an organic layer, and a second inorganic layer, the first inorganic layer, the organic layer, and the second inorganic layer are sequentially disposed in a direction away from the array substrate; and the display panel further comprises a pixel definition layer disposed between the adjacent pixel units; the pixel definition layer has an opening above the irregular groove, and a size of the opening is greater than a size of the irregular groove; part of the first inorganic layer is located on a side wall of the opening, and an orthographic projection of the part of the first inorganic layer on the array substrate is offset from an orthographic projection of the irregular interference pixel.

In a second aspect, an embodiment of the present application provides a display device, including the display panel as described in the first aspect.

The embodiments of the present application provide a display panel and a display device. The display plane includes an array substrate, a flat layer and a light-emitting functional layer, the flat layer and the light-emitting functional layer being sequentially located on the array substrate, wherein the light-emitting functional layer comprises a plurality of pixel units distributed in an array, the pixel unit comprises a display pixel and at least two irregular interference pixels, the flat layer is provided with irregular grooves of the same shape as the irregular interference pixels, an angle between at least part of an inner wall of the irregular groove and the array substrate is not equal to 90° or 180°, and the irregular interference pixel is provided in the irregular groove, so that a distance between the display pixel and the array substrate is greater than a distance between the irregular interference pixel and the array substrate. Compared with regular interference pixels such as rectangular interference pixels, irregular interference pixels are configured in the present application, which can improve the light emergent angle and improve the light emergent efficiency of the irregular interference pixels.

Compared with a single interference pixel, at least two irregular interference pixels are configured in the present application, irregular grooves are disposed in the flat layer, the irregular interference pixels are located in the irregular grooves, and the two irregular interference pixels cooperate with each other to improve the light emergent efficiency of the irregular interference pixels from different directions and angles. Correspondingly, the present application improves the interference pixels in quantity and shape to greatly improve the anti-peeping effect. Therefore, the size of the interference pixels can be appropriately reduced, which is conducive to increasing the area or density of the display pixel, thereby improving the display luminance and effect.

### BRIEF DESCRIPTION OF THE DRAWINGS

Features, advantages, and technical effects of exemplary embodiments of the present application will be described below with reference to the accompanying drawings. In the drawings, the same reference numerals are used for the same components. The accompanying drawings are not drawn to actual scale and are only used for illustrating relative positional relationships. The layer thicknesses of some parts are exaggerated for better understanding. The layer thicknesses in the drawings do not represent actual proportional relationships of the layer thicknesses.

FIG. 1 illustrates a schematic diagram showing a positional relationship between a display pixel and irregular interference pixels provided in an embodiment of the present application;

FIG. 2 illustrates a side view of a first display panel in an I direction provided in an embodiment of the present application;

FIG. 3 illustrates a side view of a second display panel in the I direction provided in an embodiment of the present application;

FIG. 4 illustrates a luminance map of a display panel in the related art and a luminance map of a display panel 100 provided in the present application;

FIG. 5 illustrates a side view of a third display panel in the I direction provided in an embodiment of the present application;

FIG. 6 illustrates a side view of a fourth display panel in the I direction provided in an embodiment of the present application;

FIG. 7 illustrates a side view of a fifth display panel in the I direction provided in an embodiment of the present application;

FIG. 8 illustrates a side view of a sixth display panel in the I direction provided in an embodiment of the present application;

FIG. 9 illustrates a side view of a seventh display panel in the I direction provided in an embodiment of the present application;

FIG. 10 illustrates a side view of an eighth display panel in the I direction provided in an embodiment of the present application;

FIG. 11 illustrates a side view of a ninth display panel in the I direction provided in an embodiment of the present application;

FIG. 12 illustrates a side view of a sixth display panel in an II direction provided in an embodiment of the present application;

FIG. 13 illustrates a flowchart of a method for fabricating a display panel provided in an embodiment of the present application; and

FIG. 14 illustrates a schematic structural diagram of a display device provided in an embodiment of the present application.

### REFERENCE NUMERALS

100. Display panel;
10. Array substrate;
20. Flat layer; 21. Irregular groove; 211. Irregular sub-groove; 212. Connecting wall;
30. Light-emitting functional layer; 31. Pixel unit; 311. Display pixel; 312. Irregular interference pixel; 313. Connecting surface; 32. Pixel definition layer;
41. First inorganic layer; 42. Organic layer; 43. Second inorganic layer;
50. Shading unit;
200. Display device.

### DETAILED DESCRIPTION

The features and exemplary embodiments of various aspects of the present application will be described in detail below. In the following detailed description, many specific details are proposed in order to provide a comprehensive understanding of the present application. However, it is obvious to those skilled in the art that the present application may be implemented without some of these specific details. The following description of the embodiments is only to provide a better understanding of the present application by illustrating examples of the present application. In the accompanying drawings and the following description, at least some of well-known structures and technologies are not shown in order to avoid unnecessary blurring of the present application; and for clarity, the sizes of regional structures may be exaggerated. Furthermore, the features, structures or characteristics described hereinafter may be combined in any suitable manner in one or more embodiments.

In the related art, interference sub-pixels are configured, and a black shading layer is disposed above the interference sub-pixels to block light emergence of the sub-pixels in a front view and limit small-angle light emergence of the interference sub-pixels, so as to affect normal pixel display and avoid large-angle visibility.

However, in the related art, the black shading layer corresponding to the interference sub-pixels reduces the aperture ratio and luminance of a display panel, resulting in poor user experience.

In view of this, the embodiments of the present application provide a display panel and a display device. At least two irregular interference pixels are configured, irregular grooves are disposed in a flat layer, and the irregular interference pixels are located in the irregular grooves, thereby improving light emergent angles of the irregular interference pixels, increasing light emergent efficiency, and then increasing display luminance of the display panel.

Specific structures and processes of the display panel and the display device provided in various embodiments of the present application are described below in conjunction with the accompanying drawings.

### An Embodiment

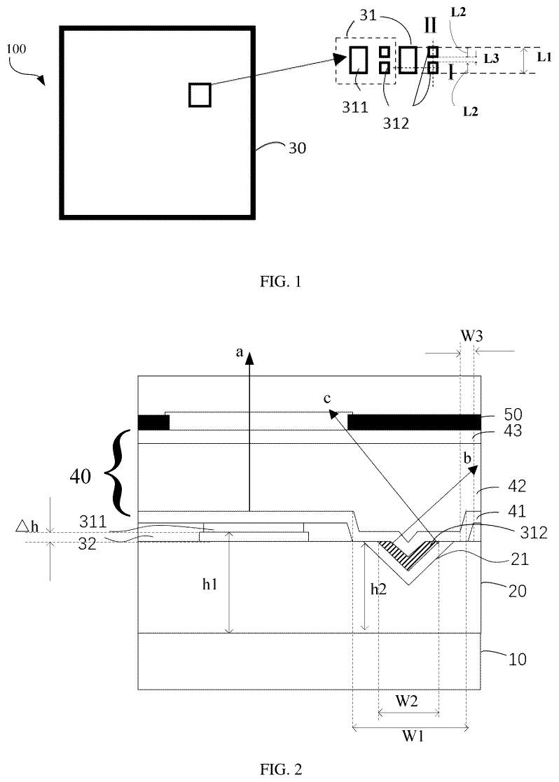

As shown in FIG. 14, a display device 200 including a display panel 100 is provided. As shown in FIG. 1 and FIG. 2, an embodiment of the present application provides a display panel 100 including an array substrate 10, a flat layer 20 and a light-emitting functional layer 30, the array substrate 10, the flat layer 20 and a light-emitting functional layer 30 are sequentially located on the array substrate 10.

As shown in FIG. 1 and FIG. 2, the light-emitting functional layer 30 includes a plurality of pixel units 31, distributed in an array, the pixel unit 31 includes a display pixel 311 and at least two irregular interference pixels 312, the flat layer 20 is provided with irregular grooves 21 of the same shape as the irregular interference pixels 312, an angle between at least part of an inner wall of the irregular groove 21 and the array substrate 10 is not equal to 90° or 180°, and the irregular interference pixel 312 is provided in the irregular groove 21, so that a distance h1 between the display pixel 311 and the array substrate 10 is greater than a distance h2 between the irregular interference pixel 312 and the array substrate 10.

FIG. 1 illustrates a schematic diagram showing a positional relationship between the display pixel 311 and the irregular interference pixels 312 provided in an embodiment of the present application. FIG. 1 is a top view of the display panel 100.

As shown in FIG. 1, the irregular interference pixel 312 has similar transverse and longitudinal dimensions, that is, quasi-square or quasi-circular, to fully utilize a light-emitting region of the interference pixel for light emergence. The present application does not limit the specific positional relationship between the display pixel 311 and the irregular interference pixels 312.

At least two irregular interference pixels 312 are provided, and the irregular interference pixels 312 have a relatively small size. Oblique light emitted by the irregular interference pixels 312 can be emergent through a gap between the two shading units 50 to improve the light emergent efficiency of the irregular interference pixels 312.

Specifically, the display panel 100 has an anti-peeping mode. When the anti-peeping mode is closed, the display pixel 311 displays normally, the irregular interference pixels 312 are turned off, and the display panel 100 can display clearly in a front or oblique view. When the anti-peeping mode is opened, the irregular interference pixels 312 are turned on, forward light emergence of the irregular interference pixels 312 is blocked by a shading unit 50, forward light emergence of the display pixel 311 is not interfered with, and the display panel 100 can display clearly in a front view; oblique light emergence of the irregular interference pixels 312 is not blocked by the shading unit 50, oblique light emergence of the display pixel 311 mixes with the oblique light emergence of the irregular interference pixels 312, and the display panel 100 cannot display clearly in an oblique view, thereby achieving an anti-peeping effect.

As shown in FIG. 2, a height difference (Δh) between the display pixel 311 and the irregular interference pixel 312 can be designed by a film thickness difference of the flat layer 20. The flat layer 20 may be made of an organic material, and its shape in different regions and different heights may be produced by a halftone mask or a double-layer flattening process without adding additional processes. The flat layer 20 may be made of an inorganic material by depositing two or more film layers and etching the film layers with a film thickness height difference.

In this embodiment, the irregular grooves 21 are disposed in the flat layer 20, and the irregular interference pixels 312 are disposed in the irregular grooves 21. The inclined portions in the irregular interference pixels 312 can significantly increase their light emergent luminance in an oblique view, improve the interference effect of the interference pixels in an oblique view, and increase the overall light emergent efficiency of the irregular interference pixels 312. Correspondingly, the present application improves the interference pixels in quantity and shape to greatly improve the anti-peeping effect. Therefore, the size of the interference pixels can be appropriately reduced, which is conducive to increasing the area or density of the display pixel 311, thereby improving the display luminance and effect.

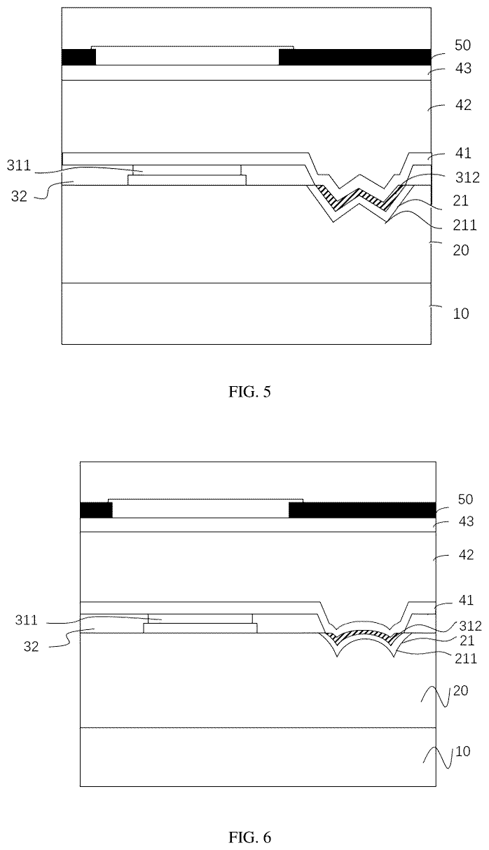

In another embodiment, as shown in FIG. 5, at least two spaced irregular grooves 21 are provided between the adjacent display pixels 311, two irregular interference pixels 312 are provided in the two irregular grooves 21 respectively, and an arrangement direction of the two irregular interference pixels 312 is a long side direction of the display pixels 311.

Specifically, as shown in FIG. 1, a length of the irregular interference pixel 312 is L2, a gap length between the two irregular interference pixels 312 is L3, a length of the display pixel 311 is L1, and a sum of lengths of the two irregular interference pixels 312 and a gap length between the two irregular interference pixels 312 (L2+L2+L3) is equal to a length of the display pixel 311, so as to maximize the sizes of the display pixel 311 and the irregular interference pixels 312 on the premise of compact arrangement of the plurality of pixel units 31, and to improve the light emergent luminance of the irregular interference pixels 312.

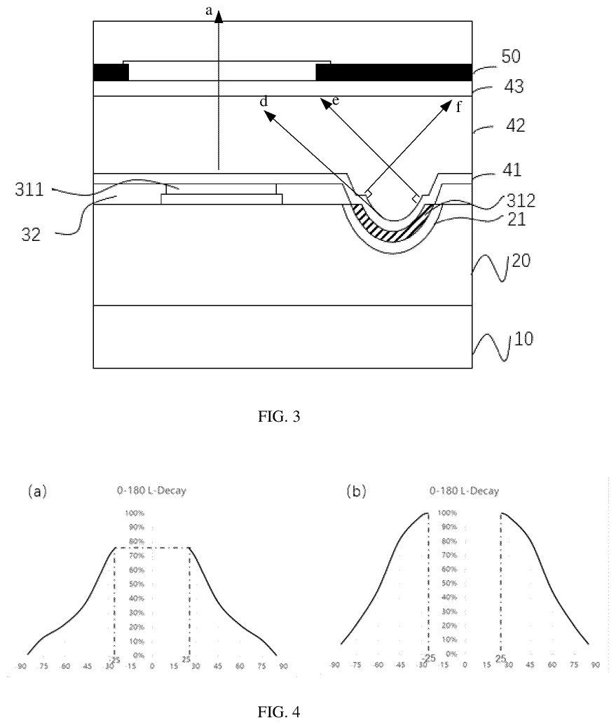

In another embodiment, as shown in FIGS. 2 and 3, the inner wall of the irregular groove 21 includes at least one curved surface or two inclined surfaces. As shown in FIG. 2, the irregular groove 21 includes two inclined surfaces, and as shown in FIG. 3, the irregular groove 21 includes one curved surface. A cross-sectional shape of the irregular interference pixel 312 includes at least one curved surface or two inclined surfaces. Light emitted by two opposite parts of the irregular interference pixel 312 forms angles with light emitted by the display pixel 311, so as to increase the light emergent rate of the irregular interference pixel 312 in an oblique view. In addition, the inclined surface or curved surface of the irregular interference pixel 312 increases the size and light-emitting area of the irregular interference pixel 312, thereby further improving the overall luminance of the display panel 100.

For example, FIG. 2 illustrates a side view of a first display panel in an I direction provided in an embodiment of the present application; and FIG. 3 illustrates a side view of a second display panel in the I direction provided in an embodiment of the present application. As shown in FIG. 2, the cross-sectional shape of the irregular interference pixel 312 and the irregular groove 21 in the display panel 100 is a V-shape, that is, the inner wall of the irregular groove 21 in FIG. 2 includes two inclined surfaces. As shown in FIG. 3, the cross-sectional shape of the irregular interference pixel 312 and the irregular groove 21 in the display panel 100 is semi-circular, that is, the inner wall of the irregular groove 21 in FIG. 3 includes a curved surface.

Interference pixels in the related art are rectangular, while the interference pixels 312 in the present application are irregular. Compared with the related art, the size of the irregular interference pixels 312 is larger, that is, compared with the related art, the present application increases the light-emitting area of the interference pixels and further improves the light emergent luminance of the interference pixels in an oblique view. In this embodiment, at least one irregular interference pixel 312 with a V-shaped cross-section is provided, and an inclined part thereof can significantly increase light emergent luminance in an oblique view, thereby improving the light emergent efficiency of the irregular interference pixel 312 and improving the overall luminance of the display panel 100. It is worth noting that the angle between the extension line of the side wall of the V-shaped groove and the light emergent direction ranges from 10° to 80°, so that more light emitted from the irregular interference pixel 312 can be emergent at an angle from the position where the shading unit is not disposed.

FIG. 4 shows a comparison of luminance maps, in which (a) shows a luminance map of interference pixels in the related art; and (b) shows a luminance map of the irregular interference pixels 312 in the present application.

It is known from FIG. 4 that there are an increase in light emergent intensity from 76% to 100% at 25° and −25° and an increase in light emergent intensity from −90° to −25° and 25° to 90°.

In another embodiment, as shown in FIG. 5 to FIG. 8, each irregular groove 21 includes at least two connected irregular sub-grooves 211, and an inner wall of each of the irregular sub-grooves 211 includes one curved surface or two inclined surfaces.

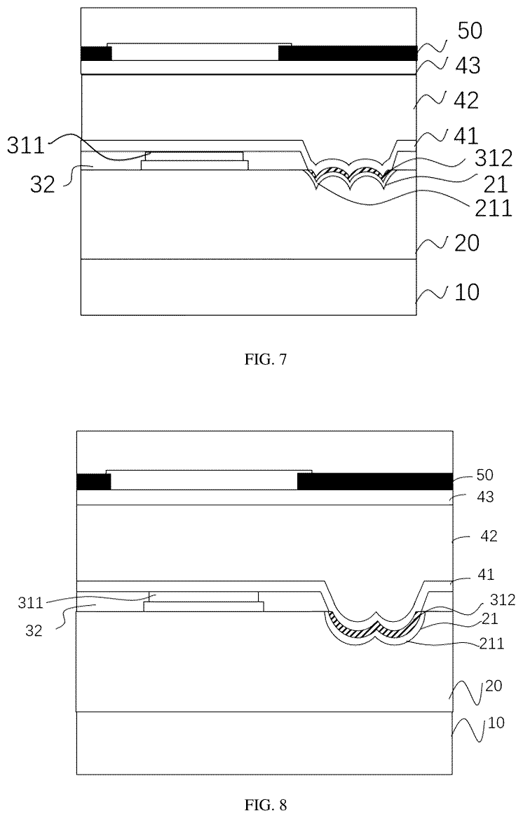

FIG. 5 illustrates a side view of a display panel in the I direction provided in an embodiment of the present application; FIG. 6 illustrates a side view of a fourth display panel in the I direction provided in an embodiment of the present application; FIG. 7 illustrates a side view of a fifth display panel in the I direction provided in an embodiment of the present application; and FIG. 8 illustrates a side view of a sixth display panel in the I direction provided in an embodiment of the present application. The cross-sectional shape of the irregular interference pixel 312 and the irregular groove 21 in the display panel 100 shown in FIG. 5 includes two consecutive V shapes, that is, the cross-sectional shape of the irregular sub-groove 211 is a V shape; the cross-sectional shape of the irregular interference pixel 312 and the irregular groove 21 in the display panel 100 shown in FIG. 6 includes two consecutive concave V shapes, that is, the cross-sectional shape of the irregular sub-groove 211 is a concave V shape; the cross-sectional shape of the irregular interference pixel 312 and the irregular groove 21 in the display panel 100 shown in FIG. 7 includes three concave V shapes, that is, the cross-sectional shape of the irregular sub-groove 211 is a concave V shape; and the cross-sectional shape of the irregular interference pixel 312 and the irregular groove 21 in the display panel 100 shown in FIG. 8 includes two consecutive convex V shapes, that is, the cross-sectional shape of the irregular sub-groove 211 is a convex V shape.

It should be particularly noted that compared with FIG. 2, the irregular grooves 21 in the display panel 100 shown in FIG. 5 to FIG. 8 are shallower, which can improve the same light emergent efficiency. Therefore, production materials, production costs, and processing difficulties can be reduced.

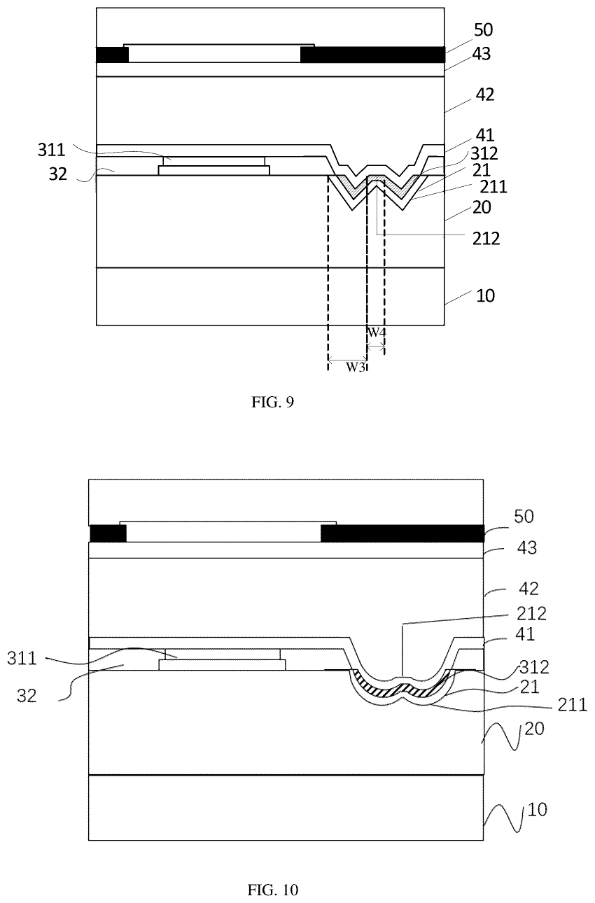

In another embodiment, as shown in FIGS. 9 and 10, a connecting wall 212 is further provided between the adjacent irregular sub-grooves 211, and the connecting wall 212 is disposed parallel to the array substrate 10, so that the irregular interference pixel on the connecting wall 212 is straight; as shown in FIG. 9, a length of the connecting wall 212 is W4, an orthographic projection length of the irregular sub-groove 211 on the array substrate is W3. In this embodiment, the length (W4) of the connecting wall 212 is ⅓ to ½ of the orthographic projection length (W3) of the irregular sub-groove on the array substrate. The scale shown in the drawings is only a schematic diagram and does not constitute a limitation on the present application.

FIG. 9 illustrates a side view of a display panel in the I direction provided in an embodiment of the present application; and FIG. 10 illustrates a side view of a display panel in the I direction provided in an embodiment of the present application. As shown in FIG. 9, the cross-sectional shape of the irregular sub-groove 211 in the display panel 100 is a V shape, and the connecting wall 212 is provided between the two irregular sub-grooves 211. The cross-sectional shape of the irregular sub-groove 211 in the display panel 100 in FIG. 10 is a convex V shape, and the connecting wall 212 is provided between the two irregular sub-grooves 211. Compared with the embodiments of FIG. 5 and FIG. 8, the connecting wall 212 is provided between the two irregular sub-grooves 211 in FIG. 9 and FIG. 10 to blunt an angle of a part connecting the two V shapes and the two convex V shapes, thereby avoiding accumulation of static charges at tips to prevent circuit burst.

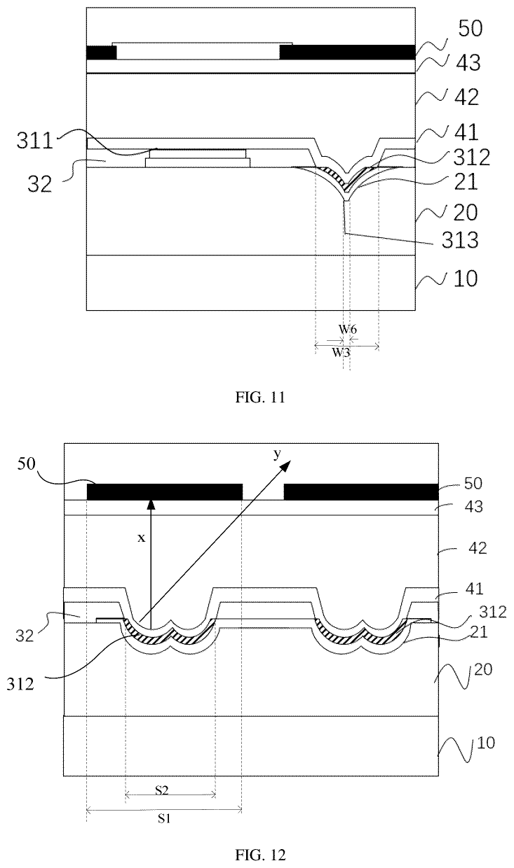

In another embodiment, as shown in FIG. 11, a connecting surface 313 is provided between the two adjacent inclined surfaces of the irregular groove 21, and the connecting surface 313 is disposed parallel to the array substrate 10, so that the irregular interference pixel 312 on the connecting surface 313 is straight; as shown in FIG. 11, a length of the connecting surface 313 is W6, an orthographic projection length of the irregular groove 21 on the array substrate 10 is W3, and the length (W6) of the connecting surface 313 is ⅓ to ½ of the orthographic projection length (W3) of the irregular groove 21 on the array substrate 10. The scale shown in the drawings is only a schematic diagram and does not constitute a limitation on the present application.

FIG. 11 illustrates a side view of a display panel in the I direction provided in an embodiment of the present application. As shown in FIG. 11, the irregular interference pixel 312 in the display panel 100 includes two concave curved surfaces and a connecting surface 313 located between the two curved surfaces. Compared with FIG. 2, the connecting surface 313 effectively blunts the angle of the part connecting the two curved surfaces, thereby avoiding accumulation of static charges at tips to prevent circuit burst.

In another embodiment, anodes of the two irregular interference pixels 312 between the adjacent display pixels 311 are connected into an integrated structure; and/or two shading units 50 are respectively disposed at intervals above the two irregular interference pixels 312 between the adjacent display pixels 311.

In another embodiment, as shown in FIG. 12, a shading unit 50 is correspondingly disposed above the two irregular interference pixels 312, and an orthographic projection of the shading unit 50 on the light-emitting functional layer 30 (the light-emitting functional layer 30 includes a plurality of pixel units 31, the pixel unit 31 includes a display pixel 311 and at least two irregular interference pixels 312) covers the two irregular interference pixels 312.

FIG. 12 illustrates a side view of the display panel in an II direction provided in an embodiment of the present application. Compared with the situation that one shading unit 50 is respectively disposed above the two irregular interference pixels 312, FIG. 12 shows that two shading units 50 are respectively disposed above the two irregular interference pixels 312, and light emitted from the outermost convex curved portion of the two irregular interference pixels 312 can be emergent through the gap between the two shading units 50, thereby further improving the light emergent efficiency of the irregular interference pixels 312.

The orthographic projection area of the shading unit 50 on the array substrate 10 is S1, the orthographic projection area of the irregular interference pixel 312 on the array substrate 10 is S2, and the orthographic projection area (S1) is greater than that the orthographic projection area (S2) of the irregular interference pixel 312 on the array substrate 10. The shading unit 50 is used for blocking the light emitted from the irregular interference pixel 312 in a front view to limit the interference pixel from emitting light at small angles. In addition, in the presence of a distance between the shading unit 50 and the irregular interference pixel 312, the orthographic projection area of the shading unit 50 on the array substrate 10 is greater than that of the irregular interference pixel 312 on the array substrate 10.

In another embodiment, as shown in FIG. 2, the extension line at the middle position of the side wall of irregular groove 21 is line b (the extension line on the side of the position indicated by 21 in the drawing), the light emergent direction of pixel 311 is indicated by a, an angle between the extension line b and the light emergent direction ranges from 10° to 80°. In another embodiment, as shown in FIG. 3, a tangent line at the middle position of the side wall of the irregular groove 21 is line d, the angle between the tangent line d and the light emergent direction a ranges from 10° to 80°.

As shown in FIG. 2, in the case where the side wall of the irregular groove 21 is a plane, an angle between an extension line b and the light emergent direction (the direction indicated by line a) ranges from 10° to 80°, or in the case where the side wall of the irregular groove 21 is a plane, an angle between the normal line (a line perpendicular to a plane indicated by 21) at any position of the side wall and the light emergent direction (the direction indicated by line a) ranges from 10° to 80°.

In the case where the side wall of the irregular groove 21 is a curved surface, an angle between a normal of the side wall except two top ends (indicated by lines e and f in FIG. 3) and the light emergent direction (the direction indicated by line a) ranges from 10° to 80°. If the angle is too small or too large, it is difficult for the light emitted from the irregular interference pixel 312 to be emergent from the position where the shading unit 50 is not disposed, and it is difficult to improve the luminance of oblique light emitted from the irregular interference pixel 312.

In another embodiment, as shown in FIG. 2, the light-emitting functional layer 30 includes a packaging layer 40 located on a light emergent side of the light-emitting functional layer 30, and the packaging layer 40 includes a first inorganic layer 41, an organic layer 42, and a second inorganic layer 43 sequentially disposed in a direction away from the array substrate 10.

The display panel further includes a pixel definition layer 32, and the pixel definition layer 32 is disposed between the adjacent pixel units 31; the pixel definition layer 32 has an opening (the projection width of the opening on the array substrate 10 in FIG. 2 is W1, that is, an opening size W1) above the corresponding irregular groove. With reference to FIG. 2, in some embodiments, the opening size W1 is greater than the size W2 of the irregular groove 21; part of the first inorganic layer 41 is located on a side wall of the opening, and an orthographic projection of the part of the first inorganic layer 41 on the array substrate 10 is offset from an orthographic projection of the irregular interference pixel 312 on the array substrate 10 (as shown in FIG. 2, the offset distance is ΔW). Therefore, more light emitted by the irregular interference pixel 312 does not pass through the first inorganic layer 41 located on the side wall of the opening, and the first inorganic layer 41 is prevented from reducing the light emergent rate. Arrows in FIG. 2 indicate exit paths of some light rays. The opening of the pixel definition layer 32 in FIG. 2 is relatively wide, so the first inorganic layer 41 located on the side wall of the opening will not block the irregular interference pixel 312. Because most of the side wall of the irregular interference pixel 312 is inclined at an angle of 10% to 80% relative to the array substrate 10, after light is emergent from the inclined side wall, the relatively large opening enables the light to avoid the first inorganic layer 41 located on the side wall of the opening. That is, the opening size of the pixel definition layer 32 matches the shape of the irregular interference pixel 312, which is beneficial to obtaining a higher light emergent rate. In another embodiment, with reference to FIGS. 3 and 5-12, the opening size of the pixel definition layer 32 may be equal to or slightly less than the size of the irregular groove 21, that is, the opening is relatively narrow because the orthographic projection of the first inorganic layer 41 located on the side wall of the opening on the array substrate 10 overlaps with the orthographic projection of the irregular interference pixel 312, and some light passes through the first inorganic layer 41 located on the side wall of the opening.

In addition, the thickness of the organic layer 42 corresponding to the irregular groove 21 is greater than that of the remaining organic layer 42. By increasing the thickness of the organic layer 42 corresponding to the irregular groove 21 without changing the thicknesses of the first inorganic layer 41 and the second inorganic layer 43 to configure the irregular groove 21, the production of defects such as holes and cracks in the first inorganic layer 41 or the second inorganic layer 43 is avoided, which is beneficial to subsequent packaging of the display panel 100.

The present application reduces the packaging difficulty of the display panel 100 by increasing the thickness of the organic layer 42 corresponding to the irregular groove 21 without changing the thicknesses of the first inorganic layer 41 and the second inorganic layer 43. The shading unit 50 is configured to ensure that the light emitted at small angles from the irregular interference pixel 312 enters human eyes.

### Another Embodiment

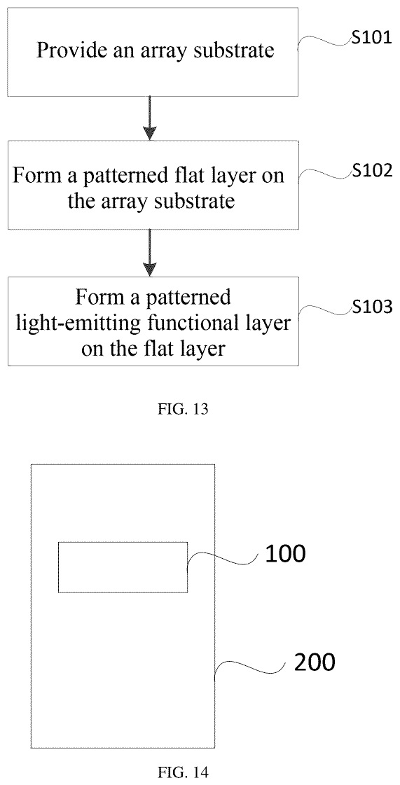

FIG. 13 illustrates a flowchart of a method for fabricating a display panel provided in an embodiment of the present application.

As shown in FIG. 13, the embodiment of the present application provides a method for fabricating a display panel, including:
step S101: providing an array substrate;
step S102: forming a patterned flat layer on the array substrate; and
step S103: forming a patterned light-emitting functional layer on the flat layer.

The flat layer is provided with irregular grooves.

The light-emitting functional layer includes a plurality of pixel units distributed in an array, the pixel unit includes a display pixel and at least two irregular interference pixels, the shape of the irregular groove is the same as that of the irregular interference pixel, and the irregular interference pixel is disposed in the irregular groove, as shown in FIG. 2, so that the distance h1 between the display pixel and the array substrate is greater than the distance h2 between the irregular interference pixel and the array substrate.

In this embodiment, the irregular grooves are disposed in the flat layer, and the irregular interference pixels are disposed in the irregular grooves. The inclined portions in the irregular interference pixels can significantly increase their light emergent luminance in an oblique view, improve the interference effect of the interference pixels in an oblique view, and increase the overall light emergent efficiency of the irregular interference pixels, thereby improving the display luminance of the display panel.

### Another Embodiment

FIG. 14 illustrates a schematic structural diagram of a display device 200 provided in an embodiment of the present application.

As shown in FIG. 14, the embodiment of the present application provides a display device 200, including the aforementioned display panel 100.

Understandably, the terms “on”, “above”, and “over” in the present application should be interpreted in a broadest way, so that “on” not only means “directly on something”, but also means “on something” with intermediate features or layers therebetween; and “above” or “over” not only means “on something” or “above”, but also means “on something” or “above” without intermediate features or layers therebetween (namely, directly on something).

The term “layer” used herein may refer to a material portion that includes a region having a thickness. The layer may extend over an entire underlying or overlying structure, or may have a smaller range than the underlying or overlying structure. In addition, the layer may be a region of a homogeneous or non-homogeneous continuous structure, with a thickness less than that of the continuous structure. For example, the layer may be located between the top and bottom surfaces of the continuous structure or between any pair of transverse planes at the top and bottom surfaces. The layer may extend laterally, vertically, and/or along a conical surface. The substrate may be a layer, which may include one or more layers, and/or may have one or more layers thereon above, and/or below. The layer may include a plurality of layers. For example, the interconnect layer may include one or more conductors and contact layers (within which contacts, interconnect lines, and/or through holes are formed) and one or more dielectric layers.

Finally, it should be noted that the above embodiments are only used for illustrating the technical solutions of the present application, rather than limiting the present application. Although the present application is described in detail with reference to the foregoing embodiments, those of ordinary skill in the art should understood that: modifications can still be made to the technical solutions recorded in the foregoing embodiments, or equivalent replacements can be made to some or all of the technical features; and these modifications or replacements do not make the essence of the corresponding technical solutions deviate from the scope of the technical solutions of the embodiments of the present application.

What is claimed is:

1. A display panel comprising an array substrate, a flat layer and a light-emitting functional layer, the flat layer and the light-emitting functional layer being sequentially located on the array substrate, wherein
the light-emitting functional layer comprises a plurality of pixel units distributed in an array, the pixel unit comprises a display pixel and at least two irregular interference pixels, the flat layer is provided with irregular grooves of the same shape as the irregular interference pixels, an angle between at least part of an inner wall of the irregular groove and the array substrate is not equal to 90° or 180°, and the irregular interference pixel is provided in the irregular groove, so that a distance between the display pixel and the array substrate is greater than a distance between the irregular interference pixel and the array substrate.

2. The display panel according to claim 1, wherein the inner wall of the irregular groove comprises at least one curved surface or two inclined surfaces.

3. The display panel according to claim 2, wherein light emitted by two opposite parts of the irregular interference pixel forms an angle with light emitted by the display pixel.

4. The display panel according to claim 2, wherein each of the irregular grooves comprises at least two connected irregular sub-grooves, and an inner wall of each of the irregular sub-grooves comprises a curved surface or two inclined surfaces.

5. The display panel according to claim 4, wherein a cross-sectional shape of the irregular interference pixel comprises at least one curved surface or two inclined surfaces.

6. The display panel according to claim 4, wherein the inner wall of the irregular groove comprises two inclined surfaces, and cross-sectional shapes of the irregular interference pixel and the irregular groove are a V shape.

7. The display panel according to claim 4, wherein a cross-sectional shape of the irregular sub-groove is a V shape, and cross-sectional shapes of the irregular interference pixel and the irregular groove are two consecutive V shapes.

8. The display panel according to claim 4, wherein a cross-sectional shape of the irregular sub-groove is a concave V shape, and cross-sectional shapes of the irregular interference pixel and the irregular groove are two consecutive concave V shapes.

9. The display panel according to claim 4, wherein a cross-sectional shape of the irregular sub-groove is a concave V shape, and cross-sectional shapes of the irregular interference pixel and the irregular groove are three concave V shapes.

10. The display panel according to claim 4, wherein a cross-sectional shape of the irregular sub-groove is a convex V shape, and cross-sectional shapes of the irregular interference pixel and the irregular groove are two consecutive convex V shapes.

11. The display panel according to claim 4, wherein the inner wall of the irregular groove comprises a curved surface, and cross-sectional shapes of the irregular interference pixel and the irregular groove are semi-circular.

12. The display panel according to claim 4, wherein a connecting wall is further provided between the adjacent irregular sub-grooves, and the connecting wall is disposed parallel to the array substrate, so that the irregular interference pixel on the connecting wall is straight; and a length range of the connecting wall is ⅓ to ½ of an orthographic projection length of the irregular sub-groove on the array substrate.

13. The display panel according to claim 12, wherein the connecting wall blunts an angle of a part connecting two V shapes or two convex V shapes.

14. The display panel according to claim 2, wherein a connecting surface is provided between the two adjacent inclined surfaces of the irregular groove, and the connecting surface is disposed parallel to the array substrate, so that the irregular interference pixel on the connecting surface is straight; and a length range of the connecting surface is ⅓ to ½ of an orthographic projection length of the irregular groove on the array substrate.

15. The display panel according to claim 1, wherein the at least two spaced irregular grooves are provided between the adjacent display pixels, the two irregular interference pixels are provided in the two irregular grooves respectively, and an arrangement direction of the two irregular interference pixels is a long side direction of the display pixels.

16. The display panel according to claim 15, wherein a sum of lengths of the two irregular interference pixels and a gap length between the two irregular interference pixels is equal to a length of the display pixel.

17. The display panel according to claim 15, wherein anodes of the two irregular interference pixels between the adjacent display pixels are connected into an integrated structure; and/or two shading units are disposed at intervals above the two irregular interference pixels between the adjacent display pixels, respectively.

18. The display panel according to claim 1, wherein an angle between an extension line or tangent line at a middle position of a side wall of the irregular groove and a light emergent direction ranges from 10° to 80°.

19. The display panel according to claim 1, further comprising:
a packaging layer located on a light emergent side of the light-emitting functional layer, the packaging layer comprising a first inorganic layer, an organic layer, and a second inorganic layer which are sequentially disposed in a direction away from the array substrate; and
a pixel definition layer disposed between the adjacent pixel units, wherein the pixel definition layer has an opening above the irregular groove, and a size of the opening is greater than a size of the irregular groove; part of the first inorganic layer is located on a side wall of the opening, and an orthographic projection of the part of the first inorganic layer on the array substrate is offset from an orthographic projection of the irregular interference pixel.

20. A display device comprising:
a display panel comprising an array substrate, a flat layer and a light-emitting functional layer, the flat layer and the light-emitting functional layer being sequentially located on the array substrate, wherein
the light-emitting functional layer comprises a plurality of pixel units distributed in an array, the pixel unit comprises a display pixel and at least two irregular interference pixels, the flat layer is provided with irregular grooves of the same shape as the irregular interference pixels, an angle between at least part of an inner wall of the irregular groove and the array substrate is not equal to 90° or 180°, and the irregular interference pixel is provided in the irregular groove, so that a distance between the display pixel and the array substrate is greater than a distance between the irregular interference pixel and the array substrate.
